(19) United States
(12) Patent Application Publication
(10) Pub. No.: US 2004/0013013 A1
(43) Pub. Date: Jan. 22, 2004

(54) Memory, module with crossed bit lines, and method for reading the memory module

(76) Inventors: Peter Beer, Tutzing (DE); Helmut Schneider, Munchen (DE)

Correspondence Address: LERNER AND GREENBERG, P.A., POST OFFICE BOX 2480, HOLLYWOOD, FL, 33022-2480, US

(21) Appl. No.: 10/609,874

(22) Filed: Jun. 30, 2003

(30) Foreign Application Priority Data
Jun. 28, 2002 (DE) 102 29 163.2

(51) Int. Cl. G11C 29/00

(52) U.S. Cl. 365/200

(57) ABSTRACT

A memory module and a method for reading a data item from a memory module allow reduced interference signal injection into adjacent bit line pairs. A crossed bit line pair is provided, with one bit line in an adjacent bit line pair being disposed between the crossed bit lines. The second bit line in the adjacent bit line pair is formed to be adjacent to the crossed bit line pair. When a data item is being read, the crossed bit line pair is preferably amplified first, with the adjacent bit line pair being amplified only subsequently. This reduces the injection of an interference signal, originating from the crossed bit line pair, into the uncrossed bit line pair.

### BACKGROUND OF THE INVENTION

Field of the Invention

The invention relates to a memory module having memory cells with bit lines which can each be connected to a memory cell via a selection transistor. In each case two bit lines form a bit line pair and one bit line pair in each case runs to one amplifier and the two bit lines in a bit line pair cross over each other. One preferred field for appying the invention is dynamic random access memories (DRAMs), in particular synchronous DRAMs (SDRAMs, DDRAMs or RDRAMs).

Dynamic random access memories (DRAMs) contain one or more arrays or banks of memory cells, which are each disposed in the form of a matrix in rows and columns. Each row has an associated row selection circuit, which is referred to as a word line, and each column has an associated column selection line, which is referred to as a bit line pair and is in the form of two conductors. Each memory cell contains a capacitor which forms the memory element and whose respective state, charged or discharged, represents the logic value of one or zero, respectively. Each memory cell has an associated selection transistor, which can be switched on by activation of the relevant word line. When the selection transistor is switched on, the capacitor is connected to one bit line in the bit line pair, in order to transfer the charge from the capacitor to the bit line, so that the stored data item produces a potential change on the bit line. The potential change can be sensed between the two bit lines in a bit line pair, since the two bit lines are at the same potential before being read. In order to assess the potential difference, each bit line pair has an associated sense amplifier, which is latched in a defined first or second state depending on whether the sensed potential difference corresponds to the logic value of one or zero for a stored data item. For selective access to selected memory cells, a selected word line is first activated by application of an activation potential. The word line to be activated is selected as a function of a row address that is provided and is decoded in a row decoder. Word line activation results in the selection transistors of all the memory cells in the address row being switched on, so that potential differences which correspond to the data in the address rows is formed on the bit line pairs of all the columns. The data is latched in the associated sense amplifiers. The latching process leads to the sensed data being amplified and, after being refreshed, being written back to the respective memory cells, as well as being available in the sense amplifiers for being called up.

After the formation of the potential differences and the amplification of the potentials on the bit lines by the sense amplifiers, the sense amplifiers are selectively connected to a data path by operation of selected transfer switches, in order either to read the latched data from the DRAM via the data path (read cycle) or to be overwritten by new data (write cycle). The sense amplifiers are selected via column selection, with the transfer switches being defined as a function of column selection signals on the basis of column addresses that are decoded in a column decoder.

During the process of reading a data item and setting up the potential differences between the bit lines, interference signals are injected into the bit lines in the bit line pair and into further bit line pairs by electromagnetic coupling. In order to avoid interference signals, it is already known for the bit lines in a bit line pair to be disposed such that they cross over at least once. It is also known for the bit lines in two or more bit line pairs to cross over one another, thus reducing the interference signals that are injected during the process of reading a data item.

### SUMMARY OF THE INVENTION

It is accordingly an object of the invention to provide a memory module with crossed bit lines, and a method for reading the memory module that overcome the above-mentioned disadvantages of the prior art devices and methods of this general type, which reduces the mutual coupling between the bit lines when reading data.

With the foregoing and other objects in view there is provided, in accordance with the invention, a memory module. The memory module contains memory cells having selection transistors, amplifiers, and bit lines connected to the selection transistors of the memory cells. The bit lines define first bit line pairs formed of two of the bit lines, the bits lines of the first bit line pairs in each case are connected to one of the amplifiers and the two bit lines in the first bit line pairs cross over each other resulting in crossed bit lines. The bit lines define second bit line pairs each having a first bit line disposed between the crossed bit lines and a second bit line.

One major advantage of the memory module according to the invention is that the coupling between bit lines in a crossed bit line pair and an adjacent bit line pair is reduced. The coupling is reduced by the bit line pair having two bit lines which are crossed at least once, and by the adjacent bit line pair having two straight bit lines, with one straight bit line in the adjacent bit line pair being disposed between the two crossed bit lines. The second bit line in the adjacent bit line pair is disposed at the side, alongside the crossed bit line pair. This configuration of the bit lines in the two bit line pairs reduces the coupling when potential differences are formed in a bit line pair, in particular in the crossed bit line pair.

In a further embodiment, the second bit line in the further bit line pair is in the form of a straight line. In this embodiment, both of the bit lines in the adjacent bit line pair are in the form of straight lines, so that the bit line pair can be configured in a simple and cost-effective manner.

In one preferred embodiment, one word line is connected to the selection transistors of the memory cells of two successive bit lines, the selection transistors of two further subsequent bit lines do not make contact with the word line, and the two selection transistors which make contact with the word line have one associated crossed bit line and one associated uncrossed bit line. This allows the circuit configuration of the memory module to be configured in a simple and cost-effective manner.

The crossed bit lines in the bit line pair are preferably connected to an amplifier circuit, which is disposed on one side of a memory cell array, and the bit lines of the adjacent bit line pair, which is not crossed, are connected to an amplifier circuit which is disposed on the opposite side of the memory cell array.

One major advantage of the method according to the invention is that the electromagnetic coupling when reading data is reduced. This effect is achieved in that, in a first amplification step, after reading two data items from two memory cells to a bit line in a crossed bit line pair and to a bit line in a bit line pair which is adjacent but is not crossed, the uncrossed bit lines are amplified first. Then, in a second amplification step, the crossed bit lines in the adjacent bit line pair are amplified. This is because it should be noted that, at this time, only that the bit line which is connected to the memory cell in a bit line pair changes its potential. The coupling that results from this to the adjacent lines is referred to as presensing coupling. Only the crossed bit line pair is insensitive to the presensing coupling from the straight bit line pair, since this coupling is distributed equally between the true bit line and the complement bit line in the crossed bit line pair. The potential change in the crossed bit line, on the other hand, leads to effective coupling, since it acts on only one of the two uncrossed bit lines over half the bit line length. The sensing, that is to say the spreading of the bit line to the full potentials VBLH and GND, is, on the other hand, symmetrical. The true bit line and the complement bit line are shifted by the same amount in opposite directions. The effective coupling to the uncrossed lines after sensing is thus zero, since the coupling between the two crossed lines is canceled out. The successive subsequent amplification reduces coupling effects during amplification of the potential differences, since the amplification of the crossed bit lines in the case of amplified uncrossed bit lines results in decreased coupling effects in comparison to uncrossed bit lines which have not yet been amplified.

In the first amplification step, a potential on a bit line in the crossed bit line pair is preferably amplified, and the potential of the other bit line of the crossed bit line pair is amplified only after an amplification value has been reached.

The layout according to the invention, has the advantage that the memory module can be configured in a cost-effective and simple manner. The chosen embodiment reduces coupling effects, while a geometric configuration that is formed from a small number of simple basic structures is nevertheless possible.

With the foregoing and other objects in view there is further provided, in accordance with the invention, a memory module. The memory modules contains memory cells each having a trench capacitor and a selection transistor with a control connection resulting in a plurality of trench capacitors and a plurality of selection transistors with a plurality of control connections. Word lines are connected to the control connections of the selection transistors. Bit lines are connected to the selection transistors, and bit line contacts are connected to the bit lines. Common active zones are connected to the bit line contacts. Two of the memory cells each being connected through one of the common active zones and through one of the bit line contacts to one of the bit lines. In a first direction, two of the trench capacitors are disposed at adjacent crossing points of the word lines and the bit lines, and subsequently in the first direction, none of the trench capacitors are disposed at two subsequent crossing points. In a second direction, two of the trench capacitors are disposed at successive crossing points of the word lines and the bit lines, and subsequently in the second direction, no further ones of the trench capacitors are disposed at two subsequent crossing points. The second direction is disposed substantially at right angles to the first direction. The trench capacitors are disposed in groups of four trench capacitors each. The trench capacitors in the groups are disposed in the four corner areas of a square, and the groups are adjacent to further ones of the groups in a diagonal direction.

Other features which are considered as characteristic for the invention are set forth in the appended claims.

Although the invention is illustrated and described herein as embodied in a memory module with crossed bit lines, and a method for reading the memory module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of a layout of a DRAM memory circuit according to the invention;

FIG. 2 is a circuit diagram of a configuration of sense amplifiers on two sides of a memory cell array;

FIG. 3 is an illustration of a reading procedure; and

FIG. 4 is a diagrammatic, plan view of a layout of a memory module according to the invention.

### DESCRIPTION OF THE PREFERRED EMBODIMENTS

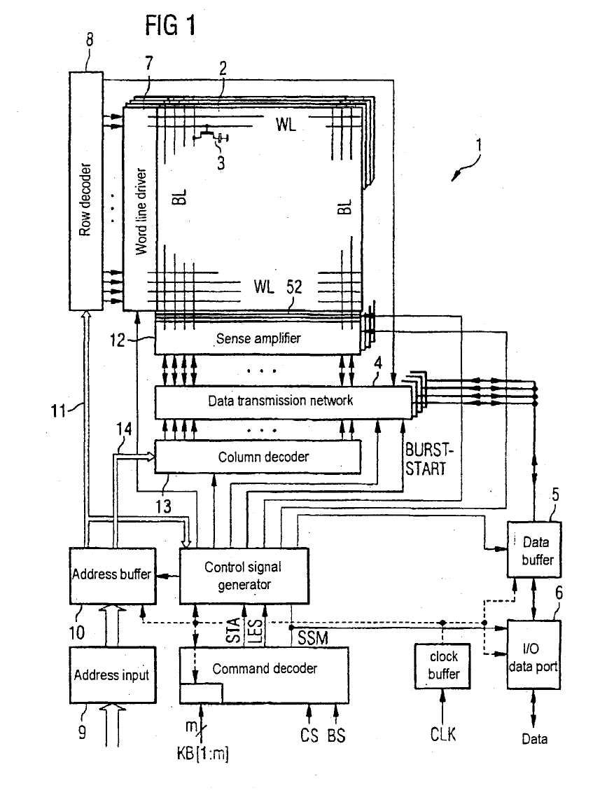

Referring now to the figures of the drawing in detail and first, particularly, to FIG. 1 thereof, there is shown a memory module 1, which is preferably integrated on a single chip. The memory module 1 contains as the memory medium memory banks 2 that are each formed from a matrix having a large number of memory cells 3. The memory cells are disposed in rows and columns, with each row having an associated word line WL, and each column having an associated bit line BL. The memory cells 3 are disposed close to the points at which the bit lines and word lines cross over. The memory cells 3 are accessed selectively for reading and writing by activation of the relevant word line WL and by connection of the relevant bit line BL to a data path, which passes via a data transmission network 4, a data buffer 5 and a bidirectional input/output data port 6 of the memory module. A large number of word line drivers 7 are provided for activation of the word lines WL for each memory bank, with each word line driver 7 being connected to an associated word line WL. Each word line driver 7 can be driven as a function of a row address by a row decoder 8. The row address can be supplied to the row decoder 8 from an address input 9 via an address buffer 10 and a row address bus 11. The bit lines BL are selectively connected to the data buffer 5 via associated sense amplifiers 12, and via data line switches, which can be controlled selectively, in the data transmission network 4. The data line switches are controlled by a column decoder 13 as a function of a column address. The column address is supplied to the column decoder 13 from the address input 9 via the address buffer 10 and via a column address bus 14.

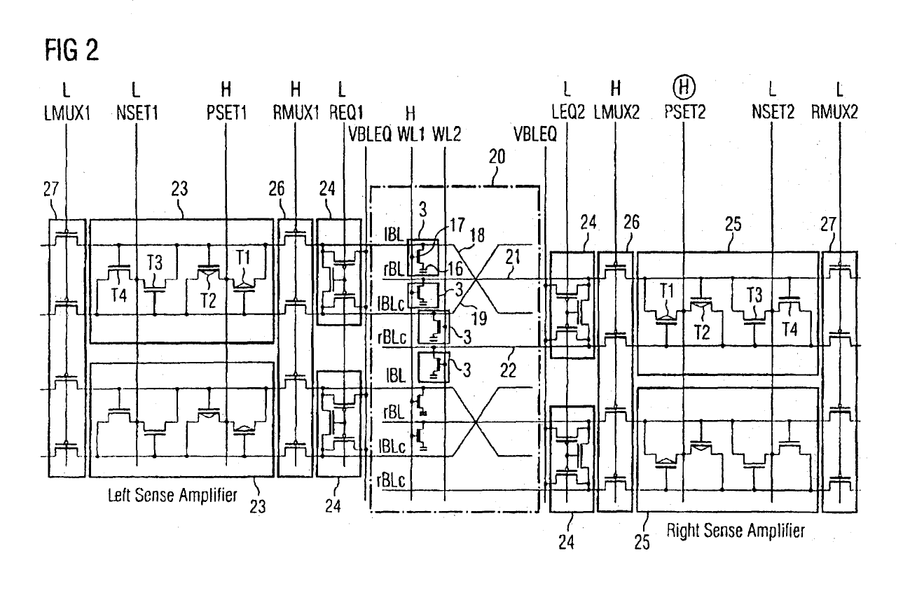

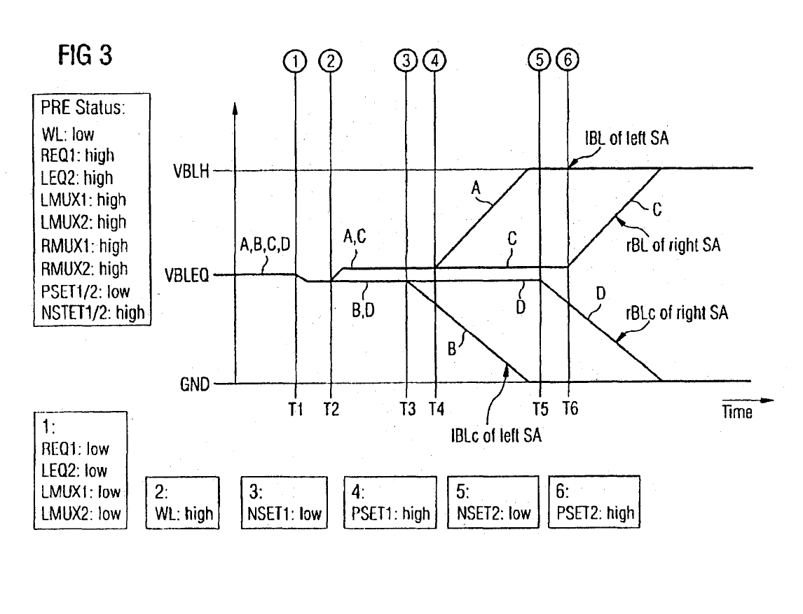

The process of the reading from a selected memory cell 3 will be explained in the following text with reference to FIGS. 2 and 3. FIG. 2 shows the memory cell 3 in any desired row x1 and any desired column y1 in the memory bank 2, and the data transmission path between the column and the data transmission network. Each memory cell 3 in the memory bank 2 is constructed in the same way as the illustrated memory cell 3. The memory cell 3 contains a capacitance, which is preferably in the form of a capacitor 16. The capacitor 16 represents the actual memory element, and its state of charge represents the data value “1” (charged) or “0” (discharged). One side of the capacitor 16 is connected to a fixed potential, and the other side is connected to a first bit line 18 via a channel through a selection transistor 17, which is in the form of an n-FET. A gate of the selection transistor 17 is connected to the associated first word line WL1. The first bit line 18 and a second bit line 19 form a bit line pair. The second bit line is likewise connected to a memory cell 3, although its selection transistor 17 is controlled by a second word line WL2. The first bit line 18 represents a true bit line, and the second bit line 19 represents a complement bit line.

In the illustrated exemplary embodiment, the selection transistor 17 is connected to the first bit line 18, which represents a true bit line. In the same way, further selection transistors whose gate connects are connected to the word line WL1 are connected to true or complement bit lines. The second word line WL2 is constructed in the same way as the first word line WL1 and is connected to selection transistors 17. The selection transistors 17 of the second word line WL2 are likewise connected to true or complement bit lines. The first bit line 18 and the second bit line 19 are in the form of crossed bit lines, and represent a first bit line pair.

A third bit line 21 is formed between the first bit line 18 and the second bit line 19. The third bit line 21 represents a true bit line, and is connected to the first word line WL1 via a selection transistor 17. A fourth bit line 22, which represents a complementary bit line, is disposed underneath the crossed first bit line pair 18, 19. The fourth bit line 22 is likewise connected to a memory cell 3, whose selection transistor 17 is controlled by the second word line WL2. The fourth bit line 22 together with the third bit line 21 represents a second, uncrossed bit line pair. The bit lines in the first bit line pair 18, 19 are passed to the left-hand side of a cell array 20, with the memory cells 3 being disposed in the cell array 20. The first bit line 18 and the second bit line 19 are connected to an amplifier circuit 23, which is disposed at the left-hand edge of the cell array 20. The second bit line pair 21, 22 is passed to the right-hand side edge of the cell array 20, and is likewise connected to a second amplifier circuit 25. A precharging circuit 24 is in each case disposed between the amplifier circuits 23, 25 and the bit lines 18, 19, 21, 22. The amplifier circuits 23, 25 represent a sense amplifier, which has a balanced input and a balanced output. The first and second amplifier circuits 23, are physically identical and contain a first transistor pair, formed from two p-channel field effect transistors (p-FETs), and a second transistor pair, formed from two n-channel field effect transistors (n-FETs) T3 and T4. The source electrodes of the p-FETs T1 and T2 are coupled to one another at a circuit point to which a first bias voltage potential PSET1 can be supplied. The source electrodes of the n-FETs T3 and T4 are coupled to one another at a circuit point to which a second bias voltage potential N-SET1 can be supplied. The drain electrodes of the transistors T1 and T3 and the gate electrodes of the transistors T2 and T4 are connected, respectively, to the first bit line 18 and to the third bit line 21. In a similar way, the drain electrodes of the transistors T2 and T4 and the gate electrodes of the transistors T1 and T3 are connected to the second bit line 19 and to the fourth bit line 22, respectively.

When the memory circuit is at the rest state, that is to say before initiation of a memory cell access, all the word lines are kept at the low level, so that the selection transistors 17 of all the memory cells 3 are switched off. The bit lines in each bit line pair are connected to one another via the precharging circuit 24, and are connected to a common potential which, as accurately as possible, is located between a low level and a high level. The precharging switches 24 are switched via REQ1 and LEQ2 signals. A selection circuit 26, which is formed by n-FET transistors, is in each case connected between the precharging circuits 24 and the associated amplifier circuit 23, 25. The selection circuit 26 makes or breaks the connection between the bit lines and the associated amplifier circuits 23, 25 depending on the drive potential. The outputs of the first and second amplifier circuits 23, 25 are connected to the data transmission network 4 via a second selection circuit 27. The second selection circuits 27 are constructed in a corresponding manner to the first selection circuits 26 and, depending on the drive, produce a conductive connection between the outputs of the amplifier circuits 23, 25 and the data transmission network 4. During the rest state, the drive signals N-SET1, P-SET1, P-SET2, N-SET2 of the first and second amplifier circuits are switched to low and high respectively, so that the first and second amplifier circuits 23, 25 are switched off. The word lines WL1, WL2 are switched to a low level. The drive circuits for the precharging circuits 24 REQ1, LEQ2 are switched to a high level, so that the two bit lines in each bit line pair which is connected to the precharging circuit 24 are connected to one another and are raised to a mean potential, which is produced by a potential line VBLEQ. The drive signals LMUX1, RMUX2 of the second selection circuits are switched to high, so that the second selection circuits 27 are switched on.

In order to initiate a cell access for reading a data item from a selected memory cell, the precharging circuits 24 are first switched off at time T1, so that the two bit lines in one bit line pair are isolated from one another, and are no longer connected to the mean voltage potential. This is done by switching the drive signals REQ1 and LEQ2 to a low level. Furthermore, the second selection circuits 27 are switched off by switching the drive signals LMUX1 and RMUX2 to a low potential.

It can be seen from the diagram in FIG. 3 that the potential on the first bit line 18 or on the second bit line 19 falls slightly after the time T1. The first word line WL1 is subsequently connected to a high potential at a time T2. After the activation of the first word line WL1, the selection transistors 17 for the first and third word lines 18, 21 are switched on. A positive charge is stored in each of the memory cells 3, which are connected to the first bit line 18 and to the third bit line 21 via the selection transistors 17, so that the potential on the first bit line 18 and on the third bit line 21 rises after the time T2. FIG. 3 shows the potentials on the first, second, third and fourth bit lines 18, 19, 21, 22. The potential on the first bit line is identified by A, that on the second bit line is identified by B, that on the third bit line is identified by C, and that on the fourth bit line is identified by D. At time T3, the control signal N-SET1 for the first amplifier circuit 23 is connected to a low potential. In this way, the lower voltage potential on the second bit line 19 is reduced by the first amplifier circuit 23. The control signal P-SET1 is set to a high level at the time T4. In consequence, the voltage potential A on the first bit line 18 is increased further. The potential A on the first bit line 18 is increased by the first amplifier circuit 23 to the maximum potential VBLH. The potential B on the second bit line 19 is reduced by the amplifier circuit 23 to the minimum potential GND. At the time T5, the control signal N-SET2 for the second amplifier circuit 25 is set to a low level. In consequence, the potential D on the fourth bit line 22 is reduced by the second amplifier circuit 25. The control signal P-SET2 is set to a high level at a later time T6. In consequence, the potential C on the third bit line 21 is increased by the second amplifier circuit 25 up to the maximum voltage potential VBLH.

Since the first bit line 18 and the second bit line 19, which represent a crossed bit line pair, are amplified first, this reduces the coupling effects during amplification of the second bit line pair, which is represented by the third bit line 21 and by the fourth bit line 22.

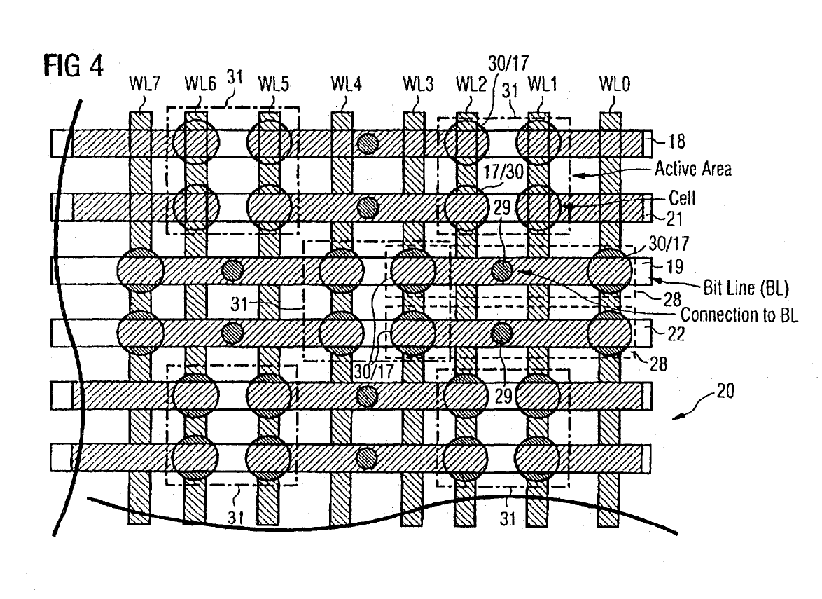

FIG. 4 shows a schematic illustration of a layout according to the invention of a memory module for the cell array 20; which has the memory cells 3 in the form of trench capacitors 30. Two memory cells 3 can in each case be connected to a common active zone 28 via a respective selection transistor 17. A bit line contact 29 is provided between the two memory cells 3 which can be connected to one active zone 28. The bit line contact 29 is connected to the bit line 18, 19, 21, 22. The word lines WL1, WL2 are disposed transversely with respect to the bit lines 18, 19 and have associated selection transistors 17. According to the invention, groups 31 of four memory trenches are disposed at each of the corner points of a square in the illustrated layout. The four trench capacitors 30 are each separated from one another only at a crossing point of a word line/bit line. The next group 31 is disposed three crossing points away in the direction of the word line or bit line. The groups 31 are disposed adjacent to one another at the corners, so that one trench capacitor 30 is disposed alongside a further trench capacitor 30 in the diagonal direction. Each trench capacitor 30 in one group is associated with a different active zone 28. Two active zones 28 are disposed between each two groups 31 of trench capacitors 30, with their trench capacitors each being separated from one another by three times the word line separation. In the proposed layout, one word line is in each case connected to two selection transistors, which have two associated successive bit lines 18, 21. The two successive bit lines are associated with different bit line pairs. Two bit lines without transistors are then formed and are then likewise associated with different bit line pairs, and trench capacitors 30 with selection transistors 17 are disposed once again only for two successive bit lines. The bit lines cross one another outside the illustrated detail.

The proposed layout is suitable for providing a memory module, which allows data to be read with reduced interference signal coupling. Furthermore, the proposed embodiment can be constructed cost-effectively, in a space-saving and simple manner.

We claim:

1. A memory module, comprising:
memory cells having selection transistors;
amplifiers; and
bit lines connected to said selection transistors of said memory cells, said bit lines defining first bit line pairs formed of two of said bit lines, said bits lines of said first bit line pairs in each case being connected to one of said amplifiers and said two bit lines in said first bit line pairs crossing over each other resulting in crossed bit lines, said bit lines defining second bit line pairs each having a first bit line disposed between said crossed bit lines and a second bit line.

2. The memory module according to claim 1, wherein said second bit line of said second bit line pairs is disposed outside an intermediate area which is bounded by said crossed bit lines of respective ones of said first bit line pairs.

3. The memory module according to claim 1, further comprising word lines disposed such that one of said word lines is respectively connected to said selection transistors of two successive ones of said bit lines, and said one of said word lines does not make contact with said selection transistors of following further ones of said bit lines, and said selection transistors to which said one of said word lines is connected include a first selection transistor connected to one of said crossed bit lines and a second selection transistor connected to one of said bit lines of a respective one of said second bit line pairs, said bit lines of said second bit line pairs being uncrossed bit lines.

4. The memory module according to claim 1, wherein said amplifiers include a first amplifier for said first bit line pairs with said crossed bit lines and a second amplifier for said second bit line pairs with said bit lines being uncrossed bit lines, said first and second amplifiers are disposed on opposite sides of a cell array.

5. The memory module according to claim 1, wherein the memory module is a dynamic random access memory module.

6. A method for reading data from a memory module, which comprises the steps of:
activating two word lines connected to selection transistors of a crossed bit line pair and of an adjacent uncrossed bit line pair, an activation of the two word lines results in one bit line in the crossed bit line pair and one bit line in the uncrossed bit line pair being connected through the selection transistors to associated memory cells;
using a first amplifier for amplifying potentials of uncrossed bit lines; and
using a second amplifier for amplifying potentials of crossed bit lines.

7. A memory module, comprising:
memory cells each having a trench capacitor and a selection transistor with a control connection resulting in a plurality of trench capacitors and a plurality of selection transistors with a plurality of control connections;
word lines connected to said control connections of said selection transistors;
bit lines connected to said selection transistors;
bit line contacts connected to said bit lines; and
common active zones connected to said bit line contacts, two of said memory cells each being connected through one of said common active zones and through one of said bit line contacts to one of said bit lines;
in a first direction, two of said trench capacitors being disposed at adjacent crossing points of said word lines and said bit lines, and subsequently in the first direction, none of said trench capacitors being disposed at two subsequent crossing points;
in a second direction, two of said trench capacitors being disposed at successive crossing points of said word lines and said bit lines, and subsequently in the second direction, no further ones of said trench capacitors are disposed at two subsequent crossing points, said second direction is disposed substantially at right angles to said first direction;
said trench capacitors disposed in groups of four of said trench capacitors, said trench capacitors in a respective one of said groups being disposed in four corner areas of a square, and said groups are adjacent to further ones of said groups in a diagonal direction.
